(19) United States
(12) Patent Application Publication
(10) Pub. No.: US 2021/0372597 A1
(43) Pub. Date: Dec. 2, 2021

(54) DEVICE COMPRISING A LEAD FRAME AND METHOD FOR PRODUCING A PLURALITY OF DEVICES

(71) Applicant: OSRAM OLED GmbH, Regensburg (DE)

(72) Inventors: Reiner WINDISCH, Pettendorf (DE); Florian BOESL, Regensburg (DE); Andreas DOBNER, Wenzenbach (DE); Matthias SPERL, Mintraching (DE)

(21) Appl. No.: 16/760,628

(22) PCT Filed: Nov. 20, 2018
(86) PCT No.: PCT/EP2018/081945

§ 371 Date: Apr. 30, 2020

(30) Foreign Application Priority Data
Nov. 22, 2017 (DE) 10 2017 127 621.1

(51) Int. Cl. F21V 19/00; F21K 9/90; F21S 4/28

(52) U.S. Cl. CPC F21V 19/002; F21V 19/0025; F21Y 2105/16; F21S 4/28; F21K 9/90

(57) ABSTRACT

A device includes a carrier and a plurality of semiconductor chips configured to generate radiation. The carrier includes a lead frame. The lead frame includes two connecting parts for external electrical contacting of the device. The semiconductor chips are arranged on the carrier. The carrier is surrounded by a casing at least in places along its entire circumference. The casing forms a side face of the device at least in places. The side face includes traces of material removal.

The present application relates to a device, in particular a radiation-emitting device, and a method of producing such a device.

Conventional light bulbs are now increasingly being replaced by light sources based on light-emitting diodes. In particular LED filaments are used, in which several LEDs are arranged on a strip-shaped substrate and enclosed by a silicone matrix. These LED filaments imitate the filament of a conventional light bulb and cause an omnidirectional radiation. Such filaments can be installed in a glass bulb which is identical to the glass bulbs of incandescent lamps. However, the production of such LED filaments is very different from the production of other LED-based components, such as surface-mountable components. This typically requires a separate production line for the LED filaments.

It is one object of the present disclosure to specify a device that can be produced easily and reliably and that has good radiation characteristics. Another object is to specify a method by means of which such devices can be produced easily and efficiently.

These objects are achieved, inter alia, by a device and a method according to the respective independent patent claims. Further designs and functionalities are the subject of the dependent patent claims.

A device is specified which is configured in particular to generate radiation, for example in the visible spectral range. The device has in particular a main direction of extension.

According to at least one embodiment of the device, the device comprises a plurality of semiconductor chips which are configured to generate radiation. For example, the semiconductor chips are designed as luminescent diode chips, in particular as light-emitting diode chips. The radiation to be generated lies, for example, in the ultraviolet, visible or infrared spectral range. For example, the device comprises at least five or at least ten semiconductor chips.

For example, the semiconductor chips have two contacts intended for external electrical contacting, the contacts being accessible on the same side of the semiconductor chip, such as a front side of the semiconductor chip. A rear side of the semiconductor chips is in particular free of electrical contacts. For example, the semiconductor chips each have an epitaxially deposited semiconductor body which is arranged on a substrate, for example a growth substrate for epitaxial deposition.

According to at least one embodiment of the device, the device comprises a carrier. For example, the expansion of the carrier along the main extension direction is at least five times as large as in a transverse direction perpendicular thereto. For example, the maximum expansion of the whole device is equal to the expansion of the carrier along the main extension direction.

For example, the semiconductor chips are arranged on the carrier and, in particular, are attached to the carrier. For example, the semiconductor chips are arranged side by side on the carrier along the longitudinal extension direction, in particular in exactly one row.

According to at least one embodiment of the device, the carrier comprises a lead frame. The lead frame comprises in particular two connecting parts for external electrical contacting of the device. The connecting parts each form a contact surface accessible from the outside for external electrical contacting, so that by applying an electrical voltage during operation of the device between the two connecting parts a current flows through the device and radiation is generated.

The lead frame is designed as a flat metal sheet, for example. For example, the lead frame contains copper or stainless steel or consists of such a material. The lead frame can also be provided with a coating at least in places, for example a coating that increases reflectivity and/or a coating that simplifies the production of a wire bond connection.

The connecting parts can also be provided for attaching the device. For example, the connecting parts of the device are designed in such a way that they can be spot-welded.

In particular, the semiconductor chips are electrically connected to each other, so that all semiconductor chips can be electrically operated via the exactly two connecting parts.

According to at least one embodiment of the device, the device comprises a casing. For example, the carrier is surrounded by the casing at least in places along its entire circumference. In particular, the casing directly adjoins the semiconductor chips and may extend continuously over all semiconductor chips of the device. A portion of the connecting parts expediently protrudes beyond the casing along the main extension direction in each case.

A portion of the connecting parts expediently protrudes beyond the front-side casing in a lateral direction in each case.

A radiation conversion material may be embedded in the casing. The radiation conversion material is configured to convert primary radiation generated by the semiconductor chips, for example radiation in the blue or ultraviolet spectral range, at least partially into secondary radiation with a peak wavelength different from the primary radiation, for example in the yellow and/or red spectral range, so that the device as a whole emits light which appears white to the human eye, for example.

According to at least one embodiment of the device, the casing forms a side face of the device at least in places.

The side face delimits the device in a direction perpendicular to the main extension direction of the carrier. In particular, the entire or substantially entire side face, for example a proportion of its area of at least 90%, may be formed by the casing.

According to at least one embodiment of the device, the side face comprises traces of material removal. The traces are, for example, traces of mechanical material removal, for example by sawing, chemical material removal, for example by etching, or material removal by coherent radiation, for example by a laser cutting process. The material removal occurs during production, especially during a singulation process, in which the devices are singulated from a composite. In particular, the device may have such traces on two opposite side faces, for example only on exactly two opposite side faces.

In at least one embodiment of the device, the device comprises a carrier and a plurality of semiconductor chips configured to generate radiation, the carrier comprising a lead frame with two connecting parts for external electrical contacting of the device. The semiconductor chips are arranged on the carrier. The carrier is surrounded by a casing at least in places along its entire circumference. The casing forms a side face of the device at least in places, and the side face comprises traces of material removal.

The device can be electrically contacted externally in an easy and reliable manner via the connecting parts of the lead frame. The casing can cover the carrier in particular also on its side faces. In particular, the radiation generated in the semiconductor chips must pass through the casing before it can exit the device. In other words, the device has no place where radiation can exit without first having passed through the casing. The risk of an excessive proportion of unconverted primary radiation in places can thus be avoided.

According to at least one embodiment of the device, the side face of the casing is perpendicular to a front side of the carrier at least in a partial area. In this context, the term “perpendicular” also includes minor deviations of not more than 10° due to manufacturing. In particular, the side face in the partial area runs parallel to the main extension direction of the device.

According to at least one embodiment of the device, the casing is formed in one piece. Within the casing there are therefore no interfaces at which partial areas of the casing adjoin each other. In particular, the casing covers both the front side of the carrier and a rear side opposite the front side.

According to at least one embodiment of the device, the carrier comprises at least one web extending to the side face of the device. In particular, the web is flush with the casing on the side face.

Seen along the main extension direction, at least one semiconductor chip is arranged in particular on both sides of the web. For example, in a view onto the side face, the web is surrounded by the casing along its entire circumference.

According to at least one embodiment of the device, a cross-section of the casing perpendicular to the main extension direction of the device is quadrangular, in particular rectangular. For example, the casing as a whole has a cuboid basic shape.

According to at least one embodiment of the device, a cross-section of the casing perpendicular to the main extension direction of the device tapers with increasing distance from the main extension direction. For example, the cross-section of the casing is curved in places. Compared to an angular cross-section, a more homogeneous radiation characteristic can thus be achieved, for example with regard to spatial and/or spectral radiation.

According to at least one embodiment of the device, at least one recess is formed in the carrier, in particular in the lead frame, for example between two adjacent semiconductor chips. The recess is filled, for example, with the casing. During operation of the device, radiation can exit through the recess. An emission of radiation on the rear side of the device can thus be promoted. For example, the recess is surrounded by the carrier, in particular by the lead frame, along its entire circumference.

According to at least one embodiment of the device, the carrier consists of the lead frame. This means that the lead frame is the only constituent part of the carrier. For example, the connecting parts of the lead frame are connected to each other in a mechanically stable manner exclusively via the casing. The semiconductor chips are arranged on the lead frame. For example, all semiconductor chips are arranged on exactly one connecting part of the lead frame.

According to at least one embodiment of the device, the carrier comprises a molded body.

The molded body is expediently designed to be electrically insulating. For example, the molded body contains a plastic. For example, the plastic can be processed by means of a molding process.

A molding process is generally understood to be a process by which a molding compound can be shaped in accordance with a given mold and, if necessary, cured. In particular, the term “molding process” includes molding, film assisted transfer molding, injection molding, transfer molding, liquid transfer molding and compression molding.

For example, the molded body is molded onto the lead frame. At the points where the molded body is molded onto the lead frame, the molded body directly adjoins the lead frame and follows the outer shape of the lead frame. For example, the molded body connects the connecting parts of the lead frame in a mechanically stable manner.

Furthermore, the molded body expediently is permeable to the radiation generated during operation of the device. For example, a basic material of the molded body absorbs at most 20%, in particular at most 5% of the incident light when radiation passes vertically through the molded body for the given vertical expansion of the molded body. A vertical direction is defined as a direction perpendicular to the front side of the carrier.

Radiation emission through the rear side of the carrier can be promoted by means of the molded body.

Particles can be added to the basic material of the molded body, for example to increase the thermal conductivity of the molded body.

According to at least one embodiment of the device, the semiconductor chips overlap with the molded body in a plan view on the device. In particular, the semiconductor chips are attached to the molded body. In particular, there is no part of the lead frame between the molded body and the semiconductor chips when viewed in a vertical direction. Seen in the vertical direction, there is only a connecting layer between the front side of the molded body and the semiconductor chips, for example an adhesive layer for attaching the semiconductor chips to the molded body.

The semiconductor chips can be arranged completely without overlapping with the lead frame. In other words, the molded body can be a part or even the only part of the carrier that overlaps with the semiconductor chips. Alternatively, the semiconductor chips can be arranged so that they overlap both with the molded body and with the lead frame.

According to at least one embodiment of the device, only the semiconductor chips closest to the ends of the device are directly connected to the lead frame in an electrically conductive manner. In other words, only one semiconductor chip is directly electrically connected to each one of the connecting parts, for example by means of a wire bond connection. A direct electrical connection between two points of the device is understood to be an electrical connection which has such a low electrical resistance that no significant voltage drop occurs between these two points during operation of the device, for example in the case of an electrically conductive connection via a metallic conductor, such as a wire bond connection.

For example, at least one semiconductor chip of the device is directly connected via wire bond connections to two semiconductor chips adjacent to said semiconductor chip, in particular on opposite sides of the semiconductor chip. The lead frame is therefore not used for a direct electrical connection to all semiconductor chips of the device.

According to at least one embodiment of the device, the device is an LED filament. For the external electrical contacting of the device in a glass bulb, the LED filament is designed in particular to be spot-weldable.

According to at least one embodiment of the device, the lead frame is self-supporting. This can mean that the lead frame is a structure which is rigid and retains its shape as a separate element. The lead frame does not need a supporting structure to retain its shape. Therefore, the lead frame is not, for example, a foil or a thin layer. Furthermore, the lead frame is designed in such a way that it can carry the semiconductor chips without the need for another supporting structure. Advantageously, no further structure is therefore needed to stabilize the lead frame. Furthermore, it is not necessary that the casing comprises a material that mechanically stabilizes the lead frame.

Furthermore, a method of manufacturing a plurality of devices is specified.

According to at least one embodiment of the method, the method comprises a step in which a carrier composite having a plurality of device regions is provided, the carrier composite comprising a lead frame. The lead frame is, for example, a continuous, structured metal sheet.

According to at least one embodiment of the method, the method comprises a step in which a plurality of semiconductor chips configured to generate radiation is arranged on the carrier composite.

According to at least one embodiment of the method, the method comprises a step in which an electrically conductive connection is established between the semiconductor chips and the lead frame. For example, adjacent semiconductor chips are each electrically conductively connected to each other by means of connecting lines, such as wire bond connections.

According to at least one embodiment of the method, the method comprises a step in which a casing is formed by means of a molding process so that the casing extends continuously over a plurality of device regions and the device regions are surrounded by the casing in particular at least in places along their entire circumference. For example, the carrier composite is placed in a casting mold for forming the casing. The term “casting mold” generally refers to the mold used for the molding process and does not imply any restriction to a particular molding process.

According to at least one embodiment of the method, the method comprises a step in which the casing is singulated between adjacent device regions into the plurality of devices, the devices each comprising a portion of the carrier composite as a carrier, a portion of the casing and a plurality of semiconductor chips.

In at least one embodiment of the method, a carrier composite having a plurality of device regions is provided, the carrier composite comprising a lead frame. A plurality of semiconductor chips configured to generate radiation is arranged on the carrier composite. An electrically conductive connection is established between the semiconductor chips and the lead frame. A casing is formed by means of a molding process so that the casing extends continuously over several device regions and the device regions are surrounded by the casing at least in places along their entire circumference. The casing is separated between adjacent device regions into the plurality of devices, the devices each comprising a portion of the carrier composite as a carrier, a portion of the casing and a plurality of semiconductor chips.

The method is preferably carried out in the order of the above listing. In particular, singulation is the last production step, so that all preceding production steps can be carried out in a composite. In particular, the electrically conductive connection to the lead frame is only established after the semiconductor chips have been attached to the molded body composite and before singulation.

The side faces of the device are created during singulation. The entire or substantially entire side faces, for example a proportion of their area of at least 90%, may be formed by the casing.

According to at least one embodiment of the method, the carrier composite and the casing are cut through in a common step during singulation. An additional cutting step is therefore not necessary.

According to at least one embodiment of the method, adjacent device regions in the provided carrier composite are each connected to one another via at least one web. For example, the casting mold mechanically supports the carrier composite in the area of the webs during the formation of the casing. A high level of planarity of the carrier composite can thus be achieved in a simplified manner.

The method described is particularly suitable for producing a device described above. Features described in connection with the device can therefore also be used for the method and vice versa.

The following effects in particular can be achieved with the device or process.

The devices can be produced with the same process sequence as other components that also have a lead frame, for example surface-mountable components. In particular, the production of the device can be carried out completely in a composite, so that no further production step is necessary after the singulation step, in which the respective casing is created. After singulation, the devices can be present in bulk form.

At the same time, the carrier can be designed in such a way that radiation can also exit through the rear side of the carrier, for example through recesses in the lead frame or through the molded body as part of the carrier. This allows omnidirectional radiation emission comparable to that of a filament, in which the LEDs are arranged on a glass, sapphire or ceramic substrate.

The lead frame can also help improve the heat dissipation from the semiconductor chips during operation of the device.

The device may be designed such that the radiation generated by the semiconductor chips must pass through the casing before it can exit the device, regardless of where the radiation exits the device. This promotes a homogeneous radiation characteristic. In particular, excessive emission of unconverted primary radiation in places can be avoided, which could lead to a color inhomogeneity of the radiated light.

Furthermore, the entire casing can be formed in one production step and cover the carrier at least in places on all sides, in particular also on the side faces of the carrier which are parallel to those side faces of the device which are only formed during singulation.

During singulation, essentially only material of the casing has to be cut through, for example, apart from optionally available webs between adjacent device regions. This simplifies the singulation process.

According to at least one embodiment of the method, the lead frame is self-supporting.

Further features, designs and functionalities will become apparent from the following description of the exemplary embodiments in connection with the figures,

in which:

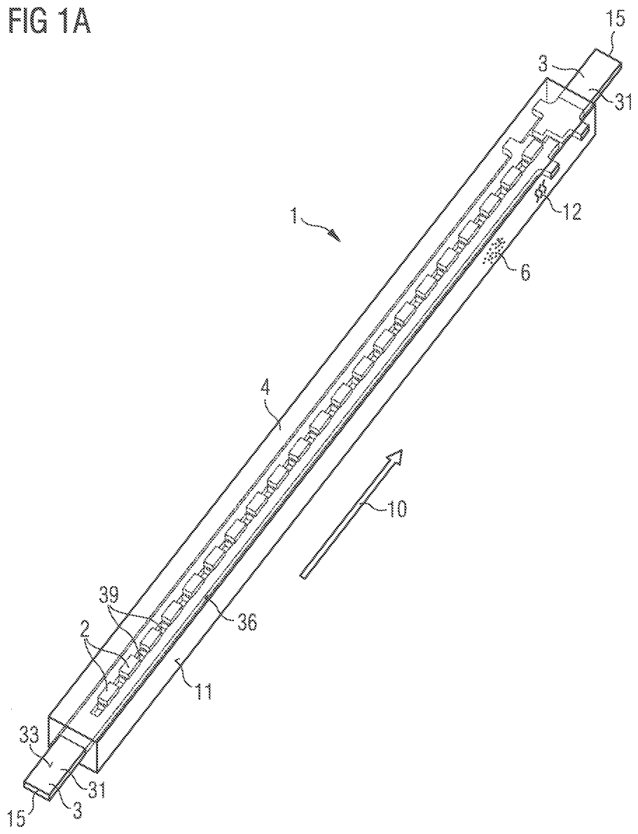

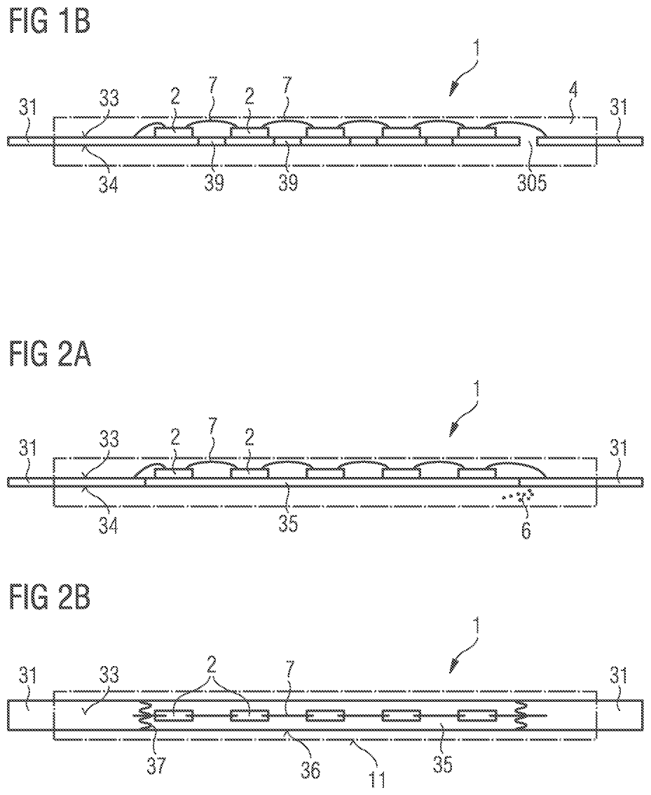

FIGS. 1A and 1B show an exemplary embodiment of a device in a perspective view (FIG. 1A) and in a schematic sectional view (FIG. 1B);

FIGS. 2A and 2B show an exemplary embodiment of a device in a schematic sectional view (FIG. 2A) and a corresponding plan view (FIG. 2B);

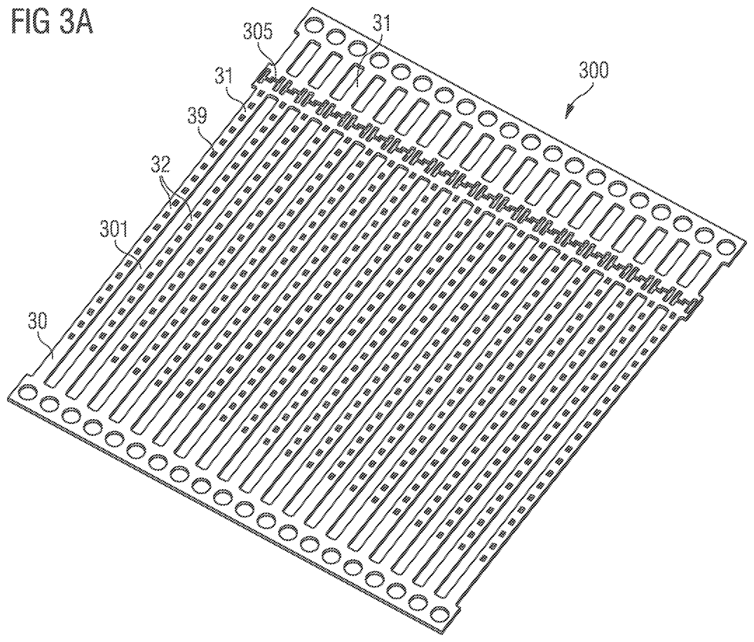

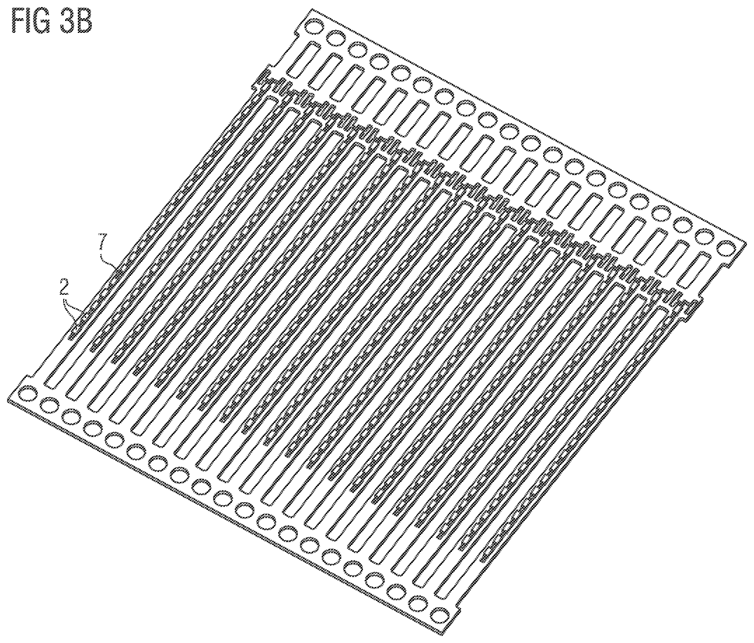

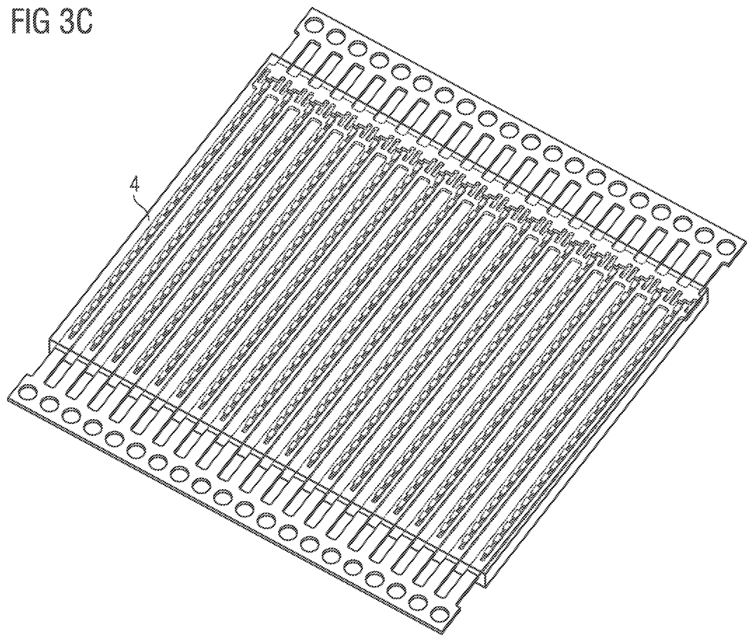

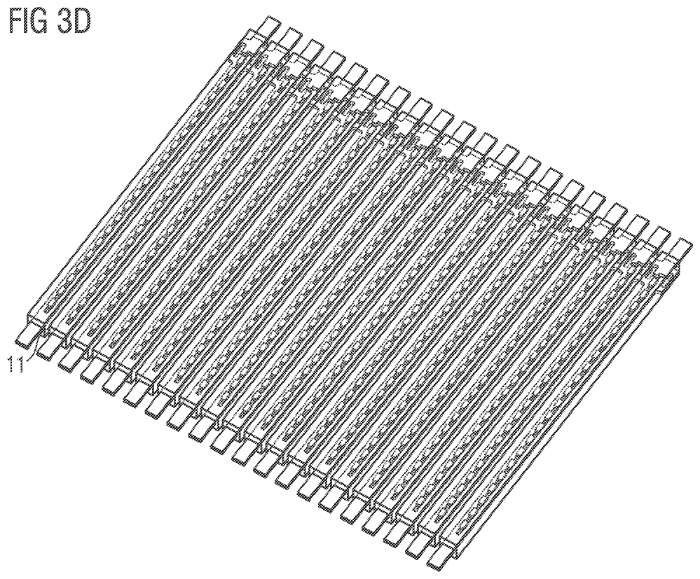

FIGS. 3A to 3D show an exemplary embodiment of a method of producing devices by means of intermediate steps each shown in a perspective view;

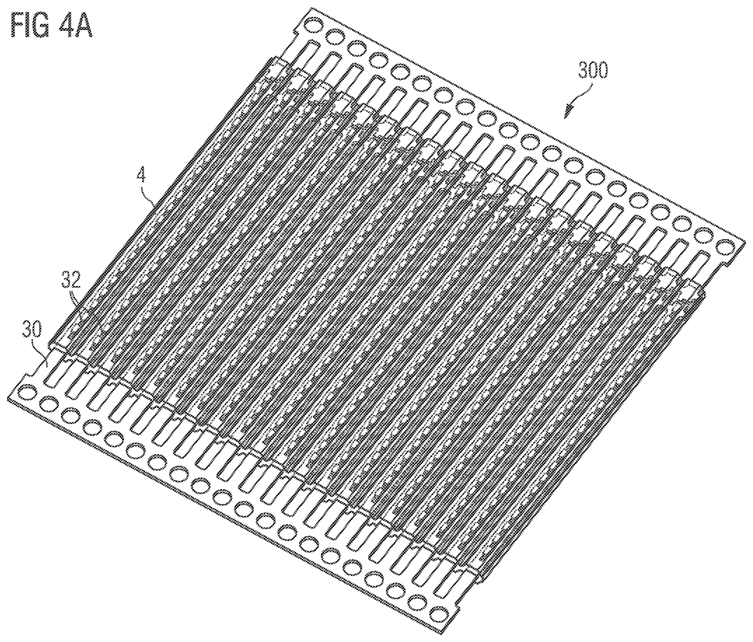

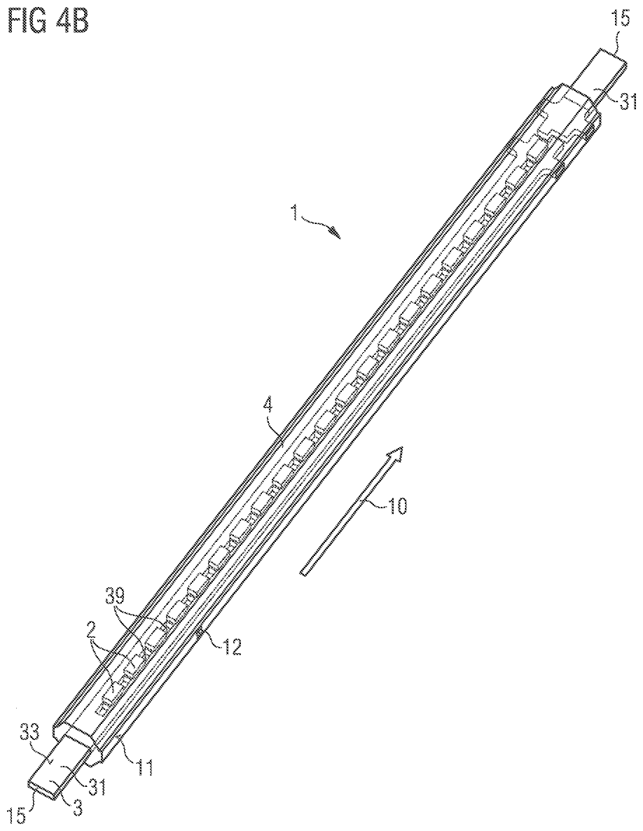

FIGS. 4A and 4B show an exemplary embodiment of a method by means of intermediate steps each shown in a perspective view, FIG. 4B showing a finished device; and

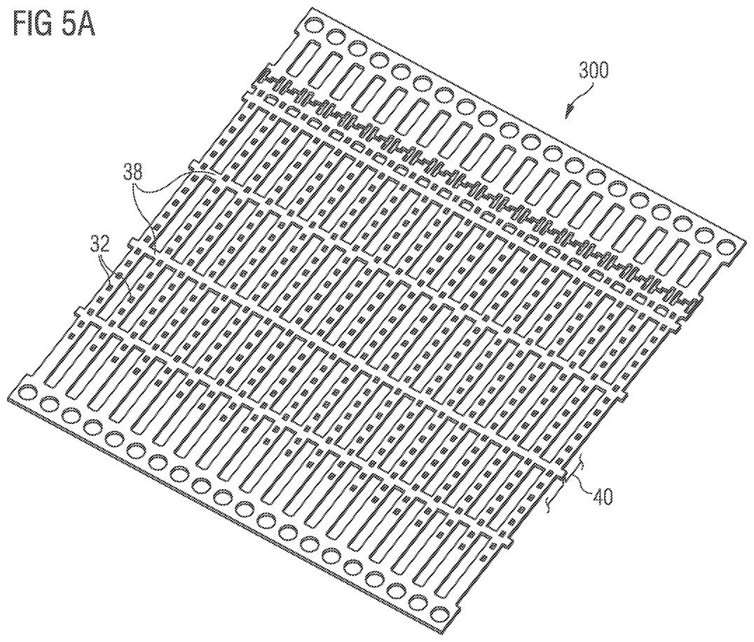

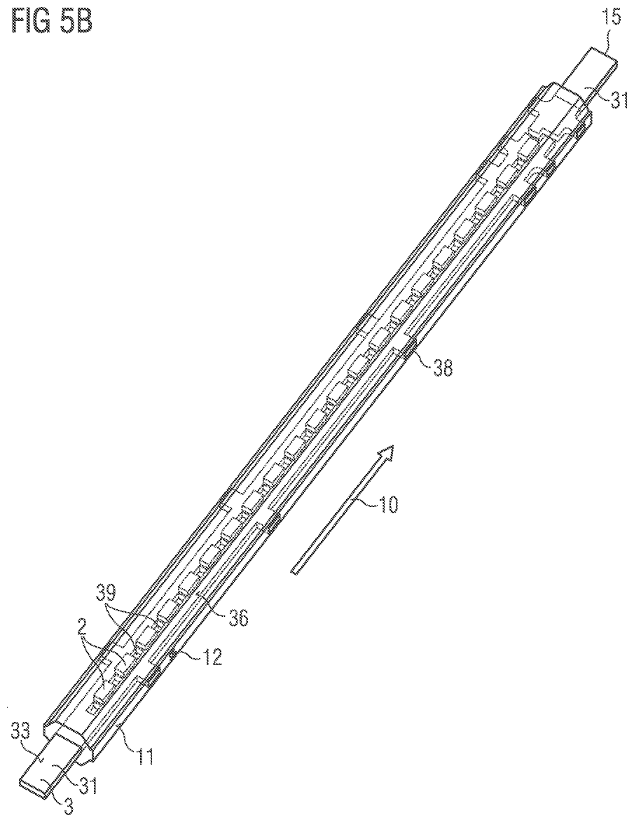

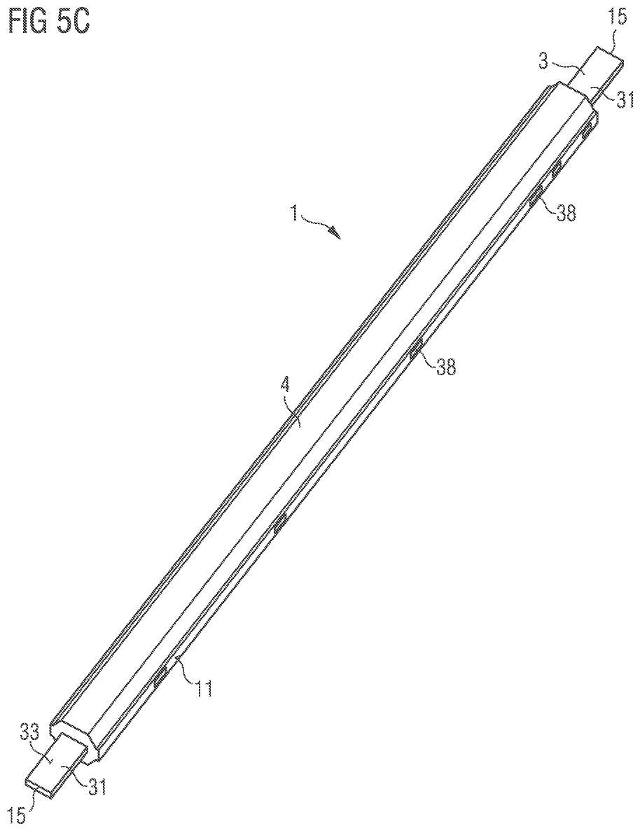

FIGS. 5A, 5B and 5C show an exemplary embodiment of a method of producing a device by means of intermediate steps each shown in a perspective view, FIGS. 5B and 5C showing a finished device in which, for better understanding, the casing is shown transparent in FIG. 5B and opaque in FIG. 5C.

Equal or similar elements as well as elements of equal function are designated with the same reference signs in the figures.

The figures and the mutual proportions of the elements depicted in the figures are not to be regarded as true to scale. Rather, individual elements and in particular layer thicknesses may be shown in exaggerated sizes for better representability and/or understanding.

FIG. 1 shows an exemplary embodiment of a device 1 having a carrier 3 and a plurality of semiconductor chips 2, the semiconductor chips being configured to generate radiation. Along a main extension direction 10, the device 1 extends between two ends 15 of the device.

The carrier 3 comprises a lead frame 30 with two connecting parts 31. The connecting parts are intended for external electrical contacting of the device 1 and form the opposite ends 15 of the device.

The semiconductor chips 2 are arranged on the carrier 3, in particular on a front side 33 of the carrier, and are attached to the carrier, for example, via a connection layer (not shown in the figures). The device also comprises a casing 4. The casing surrounds the carrier along its entire circumference, in particular in a section perpendicular to the main extension direction 10. In particular, the casing covers a side face 36 of the carrier 3. The side face 36 is parallel to the main extension direction of the device 1 and perpendicular to the front side 33 of the carrier 3.

The casing 4 forms a side face 11 of the device 1 in places. At the side face 11, the casing 4 comprises traces 12 of material removal. These are the result of a singulation process during production. The traces 12 typically extend over the entire main extension direction 10 on the side face 11. It is merely for the sake of simplicity that the traces 12 in FIG. 1A are only indicated in a partial area of the side face 11. The side face 11 of the casing is perpendicular to the front side 33 of the carrier.

A radiation conversion material 6 is arranged in the casing 4, said radiation conversion material converting primary radiation generated by the semiconductor chips 2 during operation of the device 1 at least partially into secondary radiation, so that the device emits light which appears white to the human eye, for example. The radiation conversion material 6 is expediently distributed throughout the casing 4 and is only indicated in a partial area in FIG. 1A merely for better representability.

The casing 4 contains a polymer material, such as a silicone, an epoxy or a hybrid material with a silicone or an epoxy, for example. This material can be a matrix material for the embedded radiation conversion material 6.

Along the main extension direction 10, the connecting parts 31 of the lead frame 30 are spaced apart from each other, so that the connecting parts are not directly connected to each other in an electrically conductive manner. A space 305 between the connecting parts is filled with the casing 4. The semiconductor chips 2 are each electrically conductively connected to their adjacent semiconductor chip 2 via connecting lines 7, such as wire bond connections. In each case only the semiconductor chips 2 closest to the ends 15 of the device are directly connected to the lead frame 30 in an electrically conductive manner. The semiconductor chips each have two contacts on their front side facing away from the carrier for electrical contacting by means of the connecting lines. The remaining semiconductor chips 2 are not directly electrically connected to the lead frame, but only via their respective adjacent semiconductor chips. However, the semiconductor chips 2 are thermally connected to the lead frame, so that heat loss occurring during operation of the device 1 can be efficiently dissipated from the semiconductor chips via the lead frame.

All semiconductor chips 2 of the device 1 can be energized by applying an external electrical voltage between the two connecting parts 31 so that they emit radiation during operation. For example, all semiconductor chips 2 are electrically interconnected in series.

The carrier 3, in particular the lead frame 30, has a plurality of recesses 39. The recesses 39 can be arranged between adjacent semiconductor chips 2. During operation of the device, radiation generated by the semiconductor chips 2 can pass through the recesses 39 after scattering in the casing 4, for example. The recesses 39 are filled with the casing. In this way, an emission of radiation at a rear side 34 of the carrier 3 opposite the front side 33 can be increased.

The casing 4 is formed in one piece, for example by a molding process. In a sectional view perpendicular to the main extension direction 10, the casing 4 has a quadrangular, in particular a rectangular basic shape. At the ends 15 of the device, the connecting parts 31 protrude from the casing 4.

In the exemplary embodiment shown, the carrier 3 consists of the lead frame 30. This means that the carrier 3 does not comprise any other elements. All semiconductor chips 2 of the device are arranged on the lead frame 30, in particular on exactly one connecting part 31 of the lead frame. However, it is also conceivable that one part of the semiconductor chips 2 is arranged on each one of the connecting parts 31.

The device is in particular designed as an LED filament. Along the main extension direction 10, the spatial expansion of the device is large compared to the spatial expansion perpendicular to this direction, for example at least five times as large or at least ten times as large. At the ends 15 of the device, the latter is preferably spot-weldable, so that the device can be mounted in a conventional glass bulb of a light bulb by means of spot welding and can be electrically contacted externally via the connecting parts.

Perpendicular to the main extension direction 10, the device 1 has an expansion along at least one direction, in particular along two directions perpendicular to each other, for example of between 0.5 mm and 5 mm inclusive, in particular between 1 mm and 3 mm inclusive.

For example, the semiconductor chips 2 have, along at least one direction, an edge length which is between 0.05 mm and 2 mm inclusive, in particular between 0.1 mm and 1 mm inclusive. For example, in a plan view on the front side 33 of the carrier, the semiconductor chips 2 may be rectangular or square. In the case of rectangular semiconductor chips 2, the direction along which the longest edge runs is, for example, parallel or substantially parallel, approximately with a deviation of not more than 10°, to the main extension direction 10.

For example, the carrier 3 and/or the lead frame 30 has a thickness, i.e. an expansion perpendicular to the front side 33 of the carrier, of between 50 μm and 300 μm inclusive.

The exemplary embodiment shown in FIGS. 2A and 2B essentially corresponds to the exemplary embodiment described in connection with FIGS. 1A and 1B. In contrast to the latter, the carrier 3 comprises a molded body 35 in addition to the lead frame 30. The molded body 35 is molded onto the lead frame 30 and connects the connecting parts 31 in a mechanically stable manner to each other. The connecting parts 31 can each have an interlocking structure 37. The interlocking structure 37 serves to increase the mechanical stability of the connection between the connecting parts 31 and the molded body 35.

In this exemplary embodiment, the semiconductor chips 2 are thus arranged without overlapping with the lead frame 30. The molded body 35 is suitably formed from a material that is transparent to the radiation generated by the semiconductor chips 2. The coupling out of radiation through the rear side 34 of the carrier 3 is increased by means of the molded body 35. In particular, any of the molding processes listed in the general part of the description is suitable for the production of the molded body.

The side faces 36 of the carrier are covered by the casing 4 as described in connection with FIGS. 1A and 1B. Radiation emerging from the side face 36 of the carrier, in particular radiation emerging laterally from the molded body 35, must therefore also pass through the casing 4 before it can exit from the side face 11 of the device 1. In this way, an excessive proportion of unconverted primary radiation due to radiation emerging laterally from the molded body 35 can be easily avoided or at least reduced.

FIGS. 3A to 3D schematically show an exemplary embodiment of a method of producing devices, the devices being designed as described in connection with FIGS. 1A and 1B.

As shown in FIG. 3A, a carrier composite 300 is provided, the carrier composite 300 comprising a lead frame 30. In the exemplary embodiment shown, the carrier composite consists of the lead frame 30. As described in connection with FIGS. 2A and 2B, the carrier composite 300, from which the carriers of the devices to be produced result during production, may also comprise a molded body.

The carrier composite 300 comprises a plurality of device regions 32, with the device regions being interconnected at this point. Between adjacent device regions 32, openings 301 are formed in the carrier composite 300. Adjacent device regions of the carrier composite 300 are therefore spaced apart from one another in places.

As described in connection with FIGS. 1A and 1B, the carrier composite 300 can optionally have recesses 39.

Subsequently, the semiconductor chips 2 are arranged on and attached to the carrier composite 300 (FIG. 3B). An electrical contacting of the semiconductor chips 2 is established via connecting lines 7, so that all semiconductor chips 2 of a device region 32 are electrically connected to each other and in particular also to the lead frame 30, in particular electrically in series.

A casing 4 is then formed as shown in FIG. 3C. The casing 4 directly adjoins the semiconductor chips 2 and in particular also the connecting lines 7. Furthermore, the casing 4 fills the openings 301 between adjacent device regions 32. In addition, the casing 4 fills a space 305 between the connecting parts 31 of a device region 32. The connecting parts 31 of a device region 32 are thus connected to each other in a mechanically stable manner by the casing.

A molding process in which the molding compound used is in liquid or viscous form is particularly suitable for forming the casing 4. The molding compound can be inserted into a closed or still open mold. For example, an injection molding process or an injection compression molding process such as liquid transfer molding is suitable.

The casing 4 extends continuously over a plurality of device regions 32 and can be planar on its front side as well as on its rear side opposite the front side. Hence, the casting mold used for the molding process can have a particularly simple geometry.

During the subsequent singulation process, shown in FIG. 3D, the casing 4 is cut through. This cutting produces the side faces 11 of the device 1 produced by the singulation process, which can be carried out using, for example, a sawing process or any other process mentioned in the general part of the description. Singulation produces traces characteristic of the particular singulation process, such as saw marks or other traces of material removal. The resulting casing 4 of the singulated devices 1 has a cuboid basic shape. A cross-section of the casing perpendicular to the main extension direction is quadrangular, for example rectangular.

FIGS. 4A and 4B show another exemplary embodiment of a method, FIG. 4B representing a finished device. The method and device differ from the previous description in that the casing 4 is not planar. This can be achieved, for example, by an appropriately designed casting mold. Also in this design, the casing 4 initially extends continuously over several device regions 32.

After singulation, the casing has a cross-section perpendicular to the main extension direction 10, as shown in FIG. 4B, in which the vertical expansion of the casing 4 tapers from the center of the carrier 3 towards the side faces 11. This results in a rounded cross-section of the device thus produced, in particular in the form of an LED filament. This can lead to a higher homogeneity of the radiation characteristic.

In the singulation step, the casing 4 is cut through as described in the previous exemplary embodiment. Due to the tapering cross-section, however, only a thinner layer of the casing needs to be cut through during the singulation step. The partial area of the side face 11 of the casing 4 which is created during separation again comprises traces 12 of material removal and runs perpendicular to the front side 33 of the carrier 3.

FIGS. 5A and 5B as well as 5C show another exemplary embodiment of a method and a device. In contrast to the description of FIGS. 4A and 4B, the carrier composite 300 comprises a plurality of webs 38 which connect adjacent device regions 32. This increases the mechanical stability of the carrier composite 300. In the singulation step, the webs 38 can be cut through together with the casing 4. On the side face 11 of the device, the webs 38 are surrounded by the casing 4 along their entire circumference in a side view of the device. At the side of the webs 38, the carrier 3 is surrounded by the casing 4 along its entire circumference. This is shown in FIG. 5C, where the casing 4 is shown opaque. The side face 11 of the device is thus formed by the casing 4, apart from the webs, which account for only a very small portion, typically less than 10%, less than 5% or less than 1%, of their area.

At the side face 11 of the device, in particular the casing 4 and the webs 38 are flush. To produce the casing, a casting mold 40 can be used in which the webs 38 are mechanically supported by the casting mold 40. This is shown schematically in FIG. 5A for a partial area. This simplifies a reliable positioning of the carrier composite 300 within the casting mold 40. This can also be done from opposite sides of the carrier composite, so that the carrier composite is clamped in the area of the webs when forming the casing.

A uniform overmolding of the carrier 3 is simplified. In particular, the casting mold 40 can be in direct contact with the webs 38.

As described above, in particular devices in the form of LED filaments or other omnidirectionally emitting devices can be produced in a simple and reliable manner by a method that essentially uses process steps that are also used in the production of other lead-frame-based designs of light-emitting devices.

In particular, all production steps can be carried out in a composite. In contrast to conventional LED filaments, the semiconductor chips are not placed on individual, prefabricated strip-shaped carriers. After the final singulation step, no further processing steps are required for the device.

The invention is not limited by the description based on the exemplary embodiments. Rather, the invention comprises any new feature as well as any combination of features, which in particular includes any combination of features in the claims, even if this feature or combination itself is not explicitly specified in the claims or the exemplary embodiments.

The present patent application claims the priority of German patent application DE 10 2017 127 621.1, the disclosure content of which is hereby included by way of reference.

### LIST OF REFERENCE SIGNS

1 device
10 main extension direction
11 side face
12 traces
2 semiconductor chip
3 carrier
30 lead frame
300 carrier composite
301 opening
305 space
31 connecting part
32 device region
33 front side of the carrier
34 rear side of the carrier
35 molded body
36 side face of the carrier
37 interlocking structure
38 web
39 recess
4 casing
40 casting mold
6 radiation conversion material
7 connecting line

1. A device comprising a carrier and a plurality of semiconductor chips configured to generate radiation, wherein
the carrier comprises a lead frame, and the lead frame comprises two connecting parts for external electrical contacting of the device;
the semiconductor chips are arranged on the carrier;
the carrier is surrounded by a casing at least in places along its entire circumference;
the casing forms a side face of the device at least in places; and
the side face comprises traces of material removal.

2. The device according to claim 1,
wherein the side face of the casing is perpendicular to a front side of the carrier at least in a partial area.

3. The device according to claim 1,
wherein the casing is formed in one piece.

4. The device according to claim 1,
wherein the carrier comprises at least one web which extends to the side face of the device and which is flush with the casing at the side face.

5. The device according to claim 1,
wherein a cross-section of the casing perpendicular to a main extension direction of the device is quadrangular.

6. The device according claim 1,
wherein a cross-section of the casing perpendicular to a main extension direction of the device tapers with increasing distance from the main extension direction.

7. The device according to claim 1,
wherein a recess is formed in the carrier at least between two adjacent semiconductor chips and wherein the recess is filled with the casing.

8. The device according to claim 1,
wherein the carrier consists of the lead frame.

9. The device according to claim 1,
wherein the carrier comprises a molded body formed on the lead frame.

10. The device according to claim 9,
wherein the semiconductor chips overlap with the molded body in a plan view on the device.

11. The device according to claim 1,
wherein only the semiconductor chips closest to the ends of the device are directly connected to the lead frame in an electrically conductive manner.

12. The device according to claim 1,
wherein the device is an LED filament.

13. The device according to claim 1,
wherein the lead frame is self-supporting.

14. A method for producing a plurality of devices comprising the steps of:
a) providing a carrier composite comprising a plurality of device regions, said carrier composite comprising a lead frame;
b) arranging a plurality of semiconductor chips configured to generate radiation on the carrier composite;
c) establishing an electrically conductive connection between the semiconductor chips and the lead frame;
d) forming a casing by means of a molding process so that the casing extends continuously over a plurality of device regions and the device regions are surrounded by the casing at least in places along their entire circumference; and
e) singulating the casing between adjacent device regions into the plurality of devices, the devices each comprising a portion of the carrier composite as a carrier, a portion of the casing and a portion of the plurality of semiconductor chips arranged on the carrier.

15. The method according to claim 14,
wherein the carrier composite and the casing are cut through in a common step in step e).

16. The method according to claim 14,
wherein adjacent device regions are each connected to one another via at least one web in step a) and wherein a casting mold, into which the carrier composite is inserted in step d), mechanically supports the carrier composite in the area of the webs.

17. The method according to claim 14, wherein the singulating causes each device of the plurality of devices to:
include a portion of the lead frame forming two connecting parts for external electrical contacting of the device, with the carrier being surrounded by the portion of the casing at least in places along its entire circumference and the portion of the casing forming a side face of the device at least in places; and
have traces of material removal on the side face.

18. The method according to claim 14,
wherein the lead frame is self-supporting.
